(19) United States
(12) Patent Application Publication
(10) Pub. No.: US 2018/0358323 A1
(43) Pub. Date: Dec. 13, 2018

(54) PRESSING SOLDER BUMPS TO MATCH PROBE PROFILE DURING WAFER LEVEL TESTING

(71) Applicant: INTERNATIONAL BUSINESS MACHINES CORPORATION, Armonk, NY (US)

(72) Inventors: David M. Audette, Colchester, VT (US); Sukjay Chey, Mount Kisco, NY (US); Dennis R. Conti, Essex Junction, VT (US); Marc D. Knox, Hinesburg, VT (US); Sankeerth Rajalingam, Peekskill, NY (US); Cedric Speltz, Essex Junction, VT (US); Grant Wagner, Jericho, VT (US)

(21) Appl. No.: 15/850,781

(22) Filed: Dec. 21, 2017

Related U.S. Application Data
(63) Continuation of application No. 15/620,968, filed on Jun. 13, 2017.

(51) Int. Cl. H01L 23/00; B23K 3/06

(52) U.S. Cl. CPC H01L 24/742; H01L 2224/10; B23K 3/0623; H01L 24/11

(57) ABSTRACT

A method of pressing solder bumps using a pressing apparatus before testing a wafer, including loading the wafer into the pressing apparatus, where the wafer includes a number of chips, and the wafer is aligned with respect to a test head of the pressing apparatus. The test head includes a substrate which has pressing structures arranged across a surface of the substrate facing the wafer. The pressing structures contact the solder bumps, where the solder bumps include a first surface topology and the pressing structures include a pressing surface topology prior to the contact. The caused contact includes altering a shape of each of the plurality of solder bumps, such that the plurality of solder bumps then a second surface topology after the caused contact, and the second surface topology of the solder bumps matches the pressing surface topology after the caused contact.

### BACKGROUND

The present invention relates generally to the field of semiconductor device fabrication, and more particularly to a pressing structure and method for enhancing probe array contact during wafer level testing.

During semiconductor device fabrication, wafer level testing is performed to determine the functionality of individual, partially fabricated integrated circuits (IC(s)), semiconductor devices, or semiconductor chips (“chip(s)”), of wafers or devices under test.

### SUMMARY

A method of pressing a plurality of solder bumps using a pressing apparatus prior to testing a wafer. The method includes loading the wafer into the pressing apparatus, where the wafer includes a number of chips, and the wafer is aligned with respect to a test head of the pressing apparatus. The test head includes a substrate which has pressing structures arranged across a surface of the substrate facing the wafer. The pressing structures are caused to contact a plurality of solder bumps disposed across a surface of the wafer, where the solder bumps include a first surface topology and the pressing structures comprise a pressing surface topology prior to the contact. The caused contact includes altering a shape of each of the plurality of solder bumps, such that the plurality of solder bumps includes a second surface topology subsequent to the caused contact, and the second surface topology of the solder bumps substantially matches the pressing surface topology subsequent to the caused contact.

A method of testing a wafer using a pressing apparatus and a testing apparatus including loading the wafer into the pressing apparatus, the wafer including a plurality of chips, and aligning the wafer with respect to a test head of the pressing apparatus, the test head including a substrate having pressing structures disposed across a surface of the substrate facing the wafer, and causing the pressing structures to contact a plurality of solder bumps disposed across a surface of the wafer, the plurality of solder bumps comprise a first surface topology and the pressing structures comprise a pressing surface topology prior to contact, causing the contact comprises altering a shape of each of the plurality of solder bumps, such that the plurality of solder bumps comprise a second surface topology subsequent to the caused contact, such that the second surface topology of the plurality of solder bumps substantially matches the pressing surface topology subsequent to the caused contact, and testing the wafer subsequent to the caused contact by causing a plurality of probes to contact the plurality of solder bumps, wherein the plurality of probes comprise a probe surface topology substantially matching the second surface topology during testing of the wafer.

A pressing apparatus including a first chuck including a flat mounting surface, a bottom surface of a wafer is removably mounted flush to the mounting surface of the first chuck, and the wafer includes solder bumps disposed across a top surface of the wafer, and a first test head includes first testing circuitry and a first plurality of pogo pins connected to the first testing circuitry, where the first plurality of pogo pins extending perpendicularly from a bottom surface of the first test head, a pressing card removably connected to the first test head by the first plurality of pogo pins, the pressing card including a first substrate disposed on a bottom surface of the pressing card, the pressing card includes a pressing structure for each of the plurality of solder bumps, the pressing structures extend perpendicularly from a bottom surface of the first substrate, the bottom surface of the first substrate is parallel to the top surface of the wafer, the pressing card and the wafer are moveable relative to each other in a first linear direction perpendicular to the top surface of the wafer. Movement of the wafer towards the pressing card in the first linear direction causes the pressing structures to contact the plurality of solder bumps, such that the contact results in a surface topology of the plurality of solder bumps that substantially matches the pressing surface topology.

### BRIEF DESCRIPTION OF THE DRAWINGS

The following detailed description, given by way of example and not intended to limit the invention solely thereto, will best be appreciated in conjunction with the accompanying drawings.

FIG. 1 depicts a cross-sectional view of a portion of a first test apparatus during an intermediate step of a method of wafer testing, in accordance with an embodiment of the present invention.

FIG. 2A depicts a section view, section A, of FIG. 1 during intermediate steps of a method of wafer testing, in accordance with an embodiment of the present invention.

FIG. 2B depict a section view, section A, of FIG. 1 during intermediate steps of a method of wafer testing, in accordance with an embodiment of the present invention.

FIG. 3 depicts a structure, in accordance with an embodiment of the present invention.

FIG. 4 depicts a cross-sectional view of a portion of a second test apparatus during an intermediate step of a method of wafer testing, in accordance with an embodiment of the present invention.

FIG. 5A depicts a section view, section A, of FIG. 4 during intermediate steps of a method of pressing, in accordance with an embodiment of the present invention.

FIG. 5B depicts a section view, section A, of FIG. 4 during intermediate steps of a method of pressing, in accordance with an embodiment of the present invention.

FIG. 6 depicts a section view, section A, of FIG. 4 of the first test apparatus during intermediate steps of a method of wafer testing, in accordance with an embodiment of the present invention.

FIG. 7 depicts a section view, section A, of the first test apparatus during intermediate steps of a method of wafer testing, in accordance with an embodiment of the present invention.

The drawings are not necessarily to scale. The drawings are merely schematic representations, not intended to portray specific parameters of the invention. The drawings are intended to depict only typical embodiments of the invention. In the drawings, like numbering represents like elements.

### DETAILED DESCRIPTION

Detailed embodiments of the present invention are disclosed herein for purposes of describing and illustrating claimed structures and methods that may be embodied in various forms, and are not intended to be exhaustive in any way, or limited to the disclosed embodiments. Many modifications and variations will be apparent to those of ordinary skill in the art without departing from the scope and spirit of the disclosed embodiments. The terminology used herein was chosen to best explain the principles of the one or more embodiments, the practical application or technical improvement over technologies found in the marketplace, or to enable others of ordinary skill in the art to understand the embodiments disclosed herein. As described, details of well-known features and techniques may be omitted to avoid unnecessarily obscuring the embodiments of the present invention.

References in the specification to “one embodiment”, “an embodiment”, “an example embodiment”, or the like, indicate that the embodiment described may include one or more particular features, structures, or characteristics, but it shall be understood that such particular features, structures, or characteristics may or may not be common to each and every disclosed embodiment of the present invention herein. Moreover, such phrases do not necessarily refer to any one particular embodiment per se. As such, when one or more particular features, structures, or characteristics is described in connection with an embodiment, it is submitted that it is within the knowledge of those skilled in the art to affect such one or more features, structures, or characteristics in connection with other embodiments, where applicable, whether or not explicitly described.

For purposes of the description hereinafter, the terms “upper”, “lower”, “right”, “left”, “vertical”, “horizontal”, “top”, “bottom”, “perpendicular”, “parallel”, and the like, and any derivatives thereof, shall relate to the disclosed structures and methods, as oriented in the drawing figures. The terms “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating, or semiconductor layers at the interface of the two elements.

In the interest of not obscuring disclosure of embodiments of the present invention, the following detailed description may contain certain processing steps or operations that are known in the art which may have been combined for purposes of clear description and illustration. In some instances, certain processing steps or operations that are known in the art may not be described in detail, and/or may not be described at all. It shall be understood that the following disclosure of embodiments of the present invention is relatively focused on distinctive elements, features, structures, or characteristics thereof.

Some types of wafer level testing require forming electrical connections between interconnects of a device under test and conductors of automated test equipment. The interconnects of the device under test may implement flip chip or controlled collapse chip connections (“C4(s)”), which use solder bumps formed on top of contact pads. During testing, such solder bumps may alternatively be referred to as test bumps. The conductors of the automated test equipment often include specialized testing structures, such as probes, which are used to form the requisite electrical connections with the solder bumps during testing. In such cases, the probes may be aligned, moved, or positioned, to achieve contact or engagement with the solder bumps in order to form the electrical connections.

The automated test equipment may then apply and subsequently receive test signals, input and output with respect to each of the chips of the wafer under test. Levels of functionality of each of the chips may be determined by comparison of received output test signals and expected output test signals characteristic of properly functioning chips, to distinguish between functional and dysfunctional chips.

Generally, such wafer level testing may be performed on each chip of a wafer under test simultaneously, in one “step,” or may be performed on one or more of the chips, in sequence, in a series of “steps,” until all of the chips have been tested. These types of tests may be referred to as full cluster probe testing, and step and repeat cluster testing, respectively.

The present invention relates generally to the field of semiconductor device fabrication, and more particularly, to a pressing method and structure for enhancing probe array contact during wafer testing. An array of pressing structures arranged to form a surface topology matching that formed by an array of probes used during testing. Doing so will ensure a surface topology of the array of solder bumps matches that of the array of probes during testing, thereby improving probe array contact during wafer testing. For purposes of the present description, pressing may otherwise include coining, minting, stamping, striking, molding, or otherwise forging.

Advantageously, the enhanced probe array contact according to the present disclosure can be readily implemented in current wafer level testing process flows. To that end, embodiments of the present invention allow for effective pressing operations to occur prior to testing, thereby increasing levels of accuracy and reducing the number of wafers discarded based on erroneous or inconclusive test results.

Ideally, uniform contact and low electrical resistance, also referred to in the art as contact resistance, formed between and across an array of probe contacts and an array of solder bumps residing atop chips of a wafer under test is preferable during wafer level testing. One way to achieve uniform contact and low electrical resistance includes pressing the array of solder bumps prior to testing. An embodiment by which to press the array of solder bumps is described in detail below with reference to the accompanying figures. In embodiments of the present invention, the array of solder bumps may be pressed prior to testing by using a pressing apparatus with an array of a pressing structures, to produce a surface topology of the solder bumps that matches a surface topology of the probes used during testing.

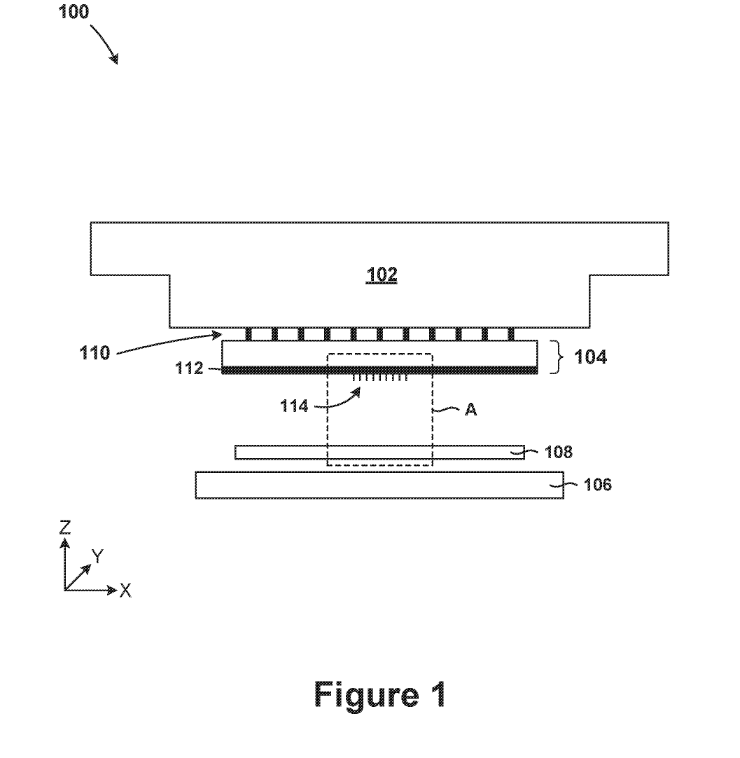

FIG. 1 depicts a cross-sectional view of a portion of a first test apparatus 100 during an intermediate step of a method of wafer testing, in accordance with an embodiment of the present invention. As depicted, FIG. 1 is representative of a view directed along a Y-axis, towards a plane formed by an X-axis and a Z-axis, with respect to the first test apparatus 100. The first test apparatus 100 may include a test head 102, a card apparatus 104, and a chuck 106.

The first test apparatus 100 represents automated test equipment, such as a wafer prober, which may perform functionality testing on a wafer under test 108 (hereinafter “wafer”). The first test apparatus 100 may include hardware and software components including instrumentation and control systems, to spatially align and position, either individually or in combination, each of the chuck 106 and the test head 102, in order to perform wafer level testing of the wafer 108. The test head 102 may be physically and electrically connected, in a removable manner, to the card apparatus 104 by pogo pins 110. The chuck 106 may removably mount, grasp, grip, or otherwise manipulate the wafer 108 prior to, during, and after testing.

In an embodiment of the present invention, the test head 102 may include wafer testing circuitry including components such as a multilayered printed circuit board (“PCB”) or a load board PCB, configured to connect to corresponding wafer testing circuitry of the card apparatus 104. The connection may be formed by, for example, a spring pin tower including the pogo pins 110.

In an embodiment of the present invention, the card apparatus 104 represents test equipment such as a probe card, which may be used in conjunction with automated test equipment. The card apparatus 104 may include a substrate 112, to which a plurality of discrete testing structures, such as probes 114, may be connected or attached. The probes 114 may be used to form electrical connections between the test head 102 and the wafer 108 during testing.

The chuck 106 may include a stage or surface configured to mount and maintain a substantially planar configuration of the wafer 108 during testing. The chuck 106 may be, for example, vacuum-actuated or electromechanically actuated.

Spatial alignment and positioning may occur along or about each of the X-axis, the Y-axis, and the Z-axis, as previously described. The wafer 108 and the card apparatus 104 may be aligned and positioned relative to each other such that mutually-facing surfaces of each are parallel and spaced apart from one another. Known probe alignment and positioning systems, for example, which use optical and electromechanical systems and techniques, may be used to position the wafer 108 with respect to the probes 114, or vice versa. As may be appreciated by those of skill in the art, any other known method of alignment and/or positioning may otherwise be used.

In an embodiment of the present invention, the card apparatus 104 may include wafer testing circuitry configured to connect to the wafer testing circuitry of the test head 102. The card apparatus 104 may include components such as a PCB, an interposer, and a substrate 112, which may include the probes 114. The PCB may be electrically connected by the interposer to the substrate 112 by, for example, interposer probes attached at one end to electrical contacts of the PCB, and at the other end to electrical contacts formed on a surface of the substrate 112. The electrical contacts formed on the surface of the substrate 112 may be electrically connected to corresponding electrical contacts, such as the probes 114, formed on an opposing surface of the substrate 112. The electrical contacts formed on opposite surfaces of the substrate 112 may be electrically connected through a thickness of the substrate 112, by way of, for example, vias, traces, or the like. The probes 114 formed on the opposing surface of the substrate 112 may generally be arranged about its center, and may be configured to form the electrical connections with the wafer 108. The substrate 112 is generally supported around its perimeter, while its center is occupied by various electrical connections and/or circuitry.

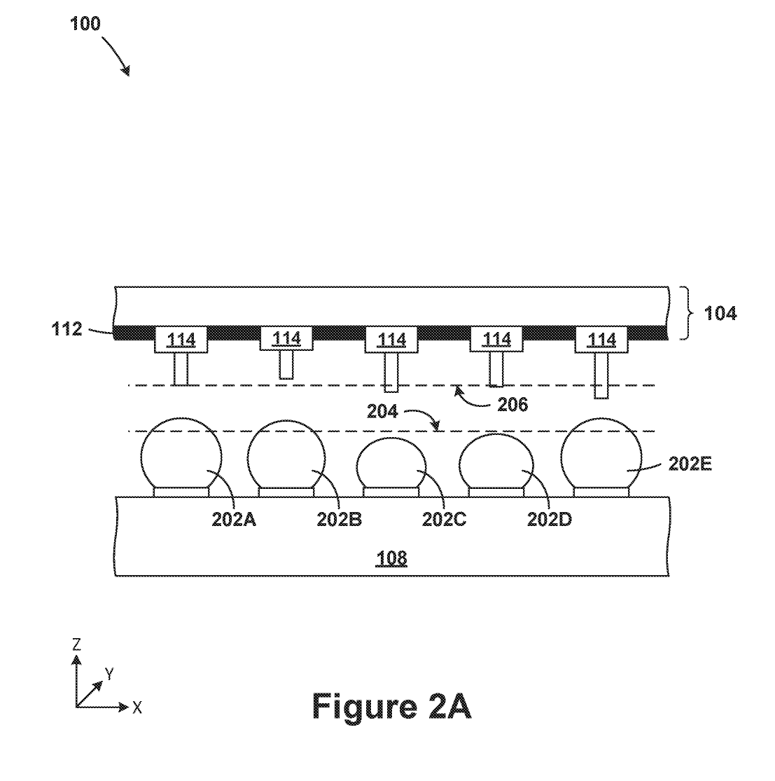

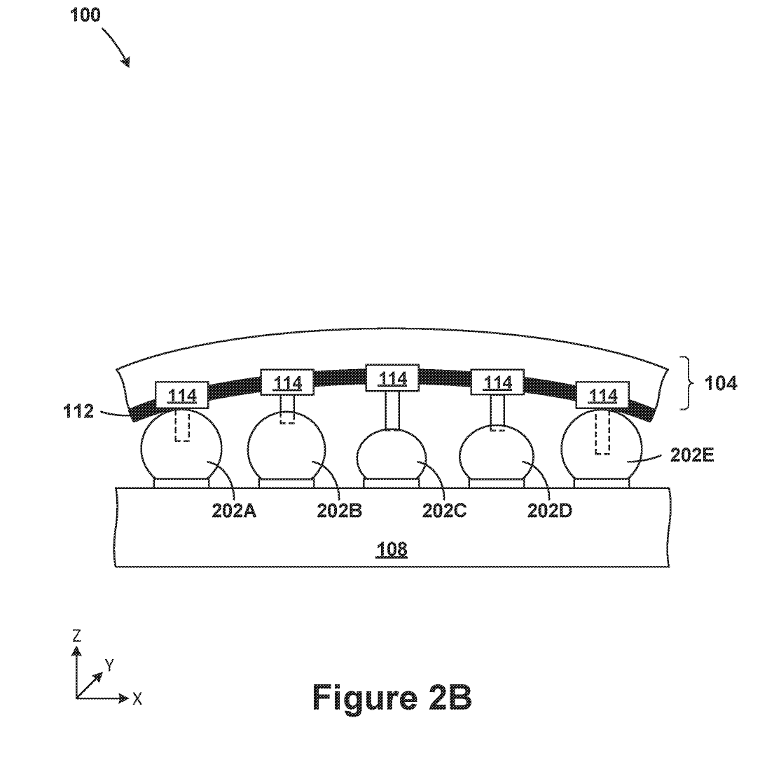

FIGS. 2A and 2B depict a section view, section A, with respect to the first test apparatus 100 of FIG. 1, during intermediate steps of a method of wafer testing, in accordance with an embodiment of the present invention. As depicted in FIG. 2A, the steps may include aligning the probes 114 with solder bumps 202A-E of the wafer 108. As depicted in FIG. 2B, the steps may further include driving or moving, either of the test head 102, the chuck 106, or both, until the probes 114 contact the solder bumps 202 and form the requisite electrical connections necessary for wafer level testing.

With reference to FIG. 2A, the substrate 112 may generally be planar or flat prior to testing. Each of the probes 114 may include ends which may be, for example, integrally formed with, or conductively attached to, the substrate 112. Each of the probes 114 may include a probe base from which an integrally formed probe tip may extend, as will be described in further detail below. In various embodiments of the present invention, a probe pitch, or an overall quantity and spacing of the probes 114 across the substrate 112, will preferably match that of the solder bumps 202 of one or more chips of the wafer 108 during testing. The probe pitch may be, for example, greater than approximately 20,000 probes per square inch. Generally, each of the solder bumps 202 may reside atop a corresponding contact pad of the one or more chips of the wafer 108. During testing, each of the probes 114 may be configured to make contact, and subsequently interconnect with, a corresponding one of the solder bumps 202.

Prior to testing, a reflow process may be performed with respect to the solder bumps 202. An overall volume of each of the solder bumps 202, both prior to and following the reflow process, may remain substantially the same; however, each of the solder bumps 202 may vary in height after the reflow process has been completed. That is, each of the solder bumps 202A-E may include relative variations in height or vertical profile with respect to each other during testing, which may have been produced as a byproduct of the reflow process. For illustrative purposes only, each of the solder bumps 202A-E are shown with exaggerated variations in height, relative to a reference line 204. Generally, each of the solder bumps 202 may have a diameter of approximately 100 micrometers, and may vary in height from approximately 5 micrometers to approximately 15 micrometers, and more particularly, from approximately 8 to 10 micrometers. For purposes of the present disclosure, the variations in height of the solder bumps 202A-E is referred to as forming or including a first topology or a first surface topology. The first topology collectively describes the variations in height, or height variation, across all of the solder bumps 202A-E.

In embodiments of the present invention, variations in height or length of the probe tips caused by manufacturing form a topology, as will be described in further detail below. Such variation may be caused, for example, by milling or forming processes used in the fabrication of the probes 114. For illustrative purposes only, each of the probes 114, and more specifically, each of the probe tips, are shown with exaggerated variations in height or length, relative to a reference line 206. Generally, each of the probe tips may vary in height from approximately 1 micrometers to approximately 10 micrometers, and more particularly, from approximately 3 to 5 micrometers. For purposes of the present disclosure, the variations in height of the probes 114 is referred to as forming or including a second topology or a second surface topology. The second topology collectively describes the variations in height, or height variation, across all of the probes 114.

With continued reference to FIG. 2A, the test head 102 or the chuck 106 may move, either individually or in combination, to align or position the probes 114 with respect to the solder bumps 202. In practice, the card apparatus 104 or the chuck 106 may be moved, either individually or in combination, along or about either the X-axis or the Y-axis to affect alignment. Alternatively, or in combination, the card apparatus 104 or the chuck 106 may be moved, either individually or in combination, along or about the Z-axis to affect alignment. Alignment or positioning preferably occurs with respect to every chip of wafer 108 that may be tested, to ensure proper contact between the probes 114 and corresponding solder bumps 202 during testing.

With reference to FIG. 2B, the test head 102 or the chuck 106, either individually or in combination, may be driven or moved to affect the proper contact between the probes 114 and the corresponding solder bumps 202, and form the requisite electrical connections required for testing. The formed electrical connections may establish an interface by which the first test apparatus 100 may apply and subsequently receive test signals, input and output with respect to the wafer 108. Travel by either of the test head 102 or the chuck 106 may primarily occur, for example, in a vertical direction parallel with the Z-axis. For example, the chuck 106 may be driven a predetermined distance in the vertical direction, resulting in a predetermined contact between the probes 114 and the corresponding solder bumps 202. Driving the chuck 106 the predetermined distance may result in applying a load of approximately 500 lbs. to the substrate 112, the solder bumps 202 and any associated components. Alternatively, rather than driving the chuck 106 the predetermined distance, it may be driven until sufficient contact between the probes 114 and the corresponding solder bumps 202 is established. Sufficient contact between the probes 114 and the corresponding solder bumps 202 may be determined by, for example, measuring the electrical resistance across the formed electrical connections during driving, and stopping travel once a predetermined electrical resistance threshold is reached.

Most notably, the above techniques often produce undesirable testing results. Specifically, the first topology of the probes 114 with respect to the second topology of the solder bumps 202 may inhibit consistent or reliable contact between the probes 114 and the solder bumps 202. Stated differently, the variations in height of the probes 114, combined with the variations in height of the solder bumps 202, may result in varying or non-uniform contact across the probes 114 and the solder bumps 202 during testing, as well as variable electrical resistance across the established interface during testing. The substrate 112 or the card apparatus 104, either individually or in combination, may experience undesirable deflection in the form of flexing, warping, or bowing, caused by contact between the probes 114 and the solder bumps 202. The most notable variations in contact and electrical resistance across the established interface due to flexing may manifest, for example, with respect to the substrate 112 from its center to its outer edges, defined by its perimeter, or vice versa. Stated differently, flexing of the substrate 112, for example, typically allows for sufficient mutual contact with respect to connections located about its perimeter, while resulting in poor mutual contact with respect to the connections located about its center. In various embodiments of the present invention, the substrate 112 may experience a maximum deflection in a direction parallel with the Z-axis that may vary approximately from 5 to 15 micrometers, and more particularly from 8 to 10 micrometers.

For example, with continued reference to FIG. 2B, the probes 114 located about the perimeter of the substrate 112 are in full contact with the solder bumps 202A and 202E. In contrast, the probes 114 located generally about the center of the substrate 112 are in partial contact with the solder bumps 202B, 202C, and 202C. In turn, the partial contact with the solder bumps 202B, 202C, and 202C results in increased, or at least variable, contact resistance across portions of the established interface, thereby producing inaccurate testing results. Further, such flexing may be caused, for example, by a combination of the manner of support of the substrate 112, that is, its support about its perimeter, and applied contact forces that may result during testing which may be experienced by the substrate 112.

For purposes of the present disclosure, the two-dimensional curve of the substrate 112 is exaggerated in FIG. 2B, and is illustrated to be representative of the problem encountered during testing. Furthermore, while flexing of the substrate 112 is illustrated as a two-dimensional curve, in practice, it may manifest in three dimensions, and occur or exist in a random manner. Such flexing may materialize without a consistent or predefined shape. As such, flexing of the substrate 112 contributes to causing non-uniform contact and variable contact resistance, exacerbating that caused by the relative variations in surface topologies, as described above.

For example, overdrive may be applied under such testing conditions in an attempt to achieve more uniform contact and lower electrical resistance. Generally, overdrive may refer to the driving or moving of either the card apparatus 104 or the chuck 106, as previously described, after already achieving contact between one or more of the probes 114 and the solder bumps 202. Such overdrive distance may exceed the predetermined distance. Overdrive may achieve more uniform contact and lower electrical resistance at the risk of causing damage to, for example, components of the wafer 108 or components of the card apparatus 104, among other components of the first test apparatus 100. For example, an excessive application of overdrive may cause an application of a contact force capable of damaging one or more chips of the wafer 108. Furthermore, the excessive application of overdrive may further induce flexing of the substrate 112.

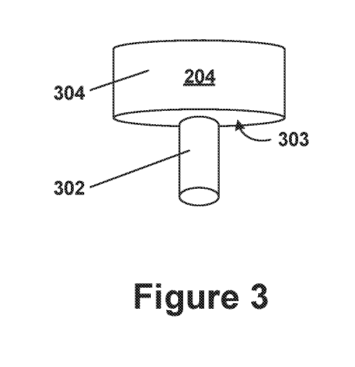

FIG. 3 depicts one of the probes 114, in accordance with an embodiment of the present invention. Each probe 114 may include a probe tip 302, which may extend from surface 303 of probe base 304. The probes 114 represent testing structures configured for use with automated test equipment, and may alternatively be referred to as probe needles, probe pins, probe contacts, or the like. As previously described, each of the probes 114 may be used to electrically conduct test signals between the test head 102 and the wafer 108.

In an embodiment of the present invention, the probe tip 302 and the probe base 304 may be electrically conductive, and may be configured for electrical connection to the substrate 112, as previously described. The probe tip 302 may be configured to contact and interconnect with a corresponding solder bump, as previously described, to thereby form an electrical connection with the wafer 108.

In an embodiment of the present invention, each of the probes 114 may be formed of one or more electrically conductive materials. Additionally, each of the probes 114, that is, with respect to the probe base 304, the surface 303, and the probe tip 302, either individually or in combination, may include metallic or alloy plating to obtain high conductivity, wear-resistance, non-cohesiveness, low impedance, or the like. For example, the probes 114 may be formed of copper material, and may include alloy plating in the form of nickel and gold.

In an embodiment of the present invention, the probe tip 302 may be concentrically-arranged and integrally formed with respect to a corresponding probe base 304, so as to extend in a generally perpendicular direction away from a surface 303 of the corresponding probe base 304. The probe tip 302 may be shaped so as to form a flat surface or a point, and may generally include a substantially circular cross-section. The probe base 304 may be cylindrical or tubular in form, and may include a diameter of approximately 130 micrometers and a height of approximately 18 micrometers. The probe tip 302 may be cylindrical or tubular in form, and may include a diameter of approximately 25 micrometers and a height of approximately 20 micrometers. The probe tip 302 may be configured to exert a pressure upon a corresponding solder bump 202 during testing, sufficient to overcome a surface tension upon contact thereof.

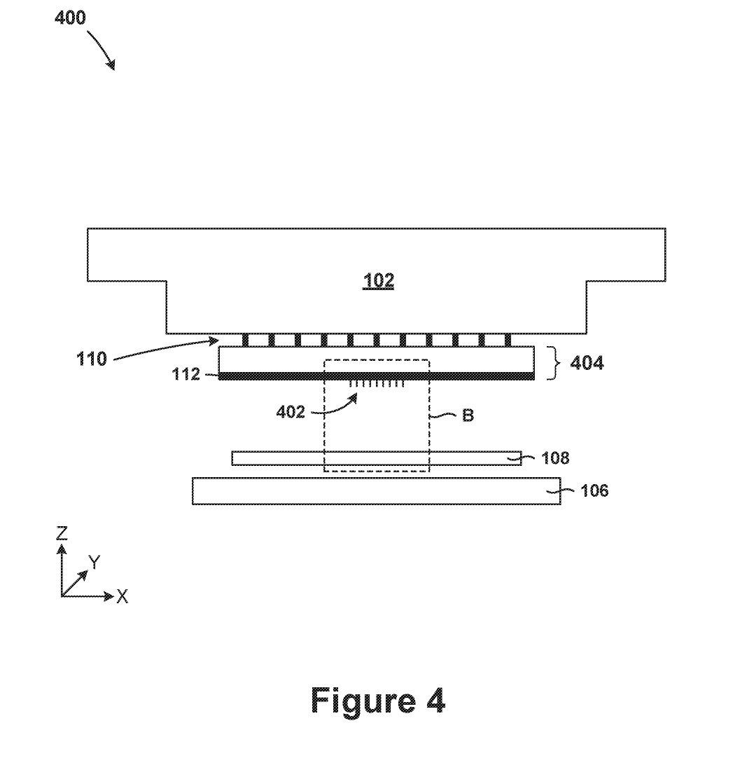

FIG. 4 depicts a cross-sectional view of a portion of a second test apparatus 400 during an intermediate step of a method of pressing, in accordance with an embodiment of the present invention. As depicted, FIG. 4 is representative of a view directed along a Y-axis, towards a plane formed by each of an X-axis and a Z-axis, with respect to the second test apparatus 400. The second test apparatus 400 may include the test head 102, a card apparatus 404, and the chuck 106.

The second testing apparatus 400 represents automated test equipment, such as a pressing apparatus, which may be configured to perform one or more pressing operations on the wafer 108 prior to testing, as previously described, by the first test apparatus 100. The second test apparatus 400 may be completely or substantially similar to the first test apparatus 100; however, the second test apparatus 400 may include differences with respect to pressing structures 402, which may replace the probes 114.

In an embodiment of the present invention, the card apparatus 404 represents test equipment, such as a pressing card, which may be used in conjunction with automated test equipment. The card apparatus 404 may be completely or substantially similar to the card apparatus 104, as previously described; however, the card apparatus 404 may include differences with respect to the pressing structures 402, which may replace the probes 114. As such, the card apparatus 404 may include circuitry, which is identical or substantially similar to, the wafer testing circuitry of the card apparatus 104. The pressing circuitry may be configured to connect to the wafer testing circuitry of the test head 102, as previously described. The card apparatus 404 may include the substrate 112, as previously described, to which the pressing structures 402, may be attached in place of the probes 114. The pressing structures 402 may be used to press the solder bumps 202 prior to testing of the wafer 108. In various embodiments, the card apparatus 404 may be interchangeable with the card apparatus 104, or may take the form of a modified card apparatus 104, as described in further detail below.

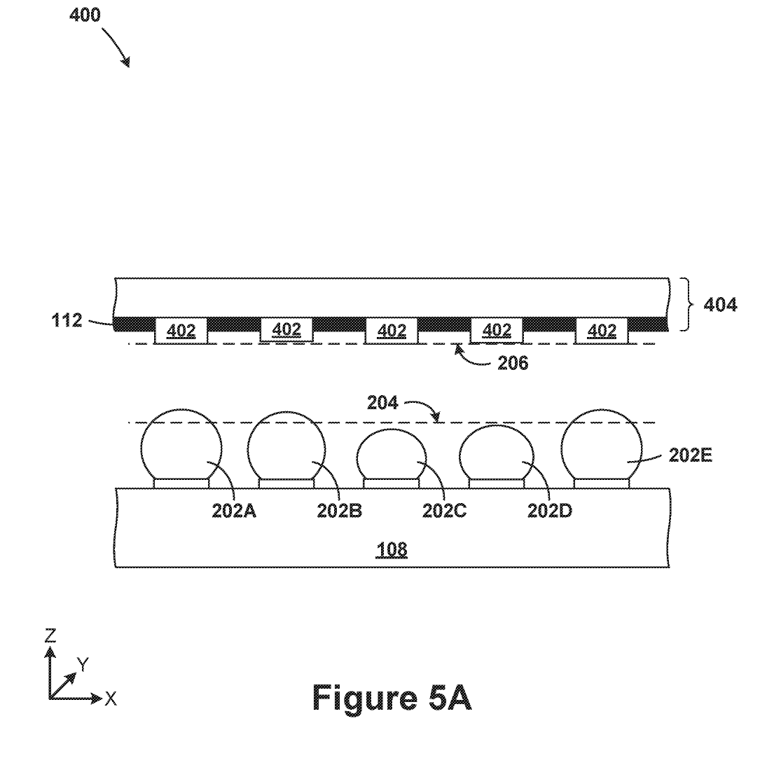

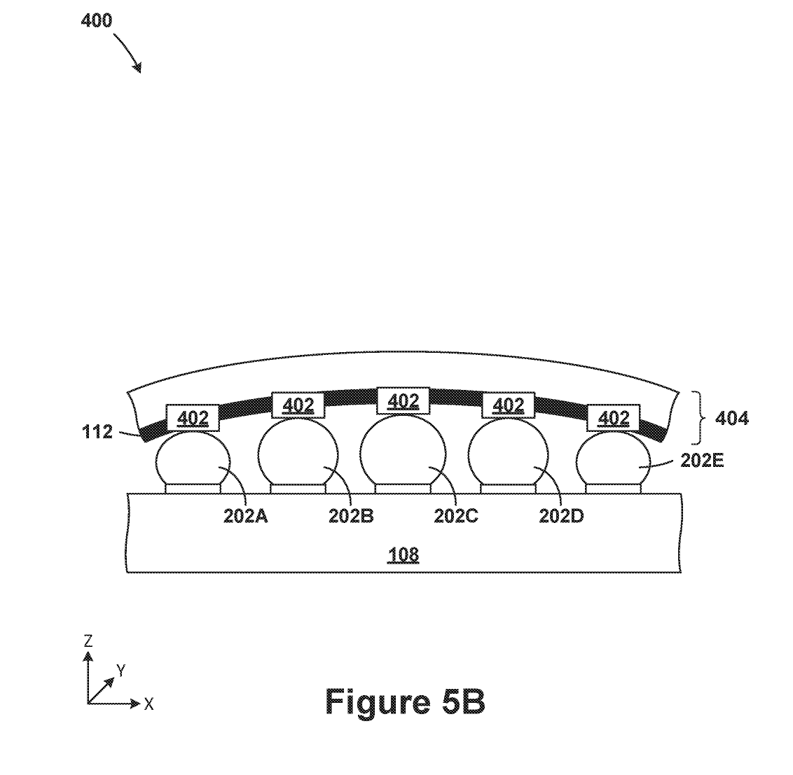

FIGS. 5A and 5B depict a section view, section B, with respect to the second test apparatus 400 of FIG. 4, during intermediate steps of a method of pressing, in accordance with an embodiment of the present invention. As depicted in FIG. 5A, the steps may include aligning the pressing structures 402 with the solder bumps 202A-E of the wafer 108. As depicted in FIG. 2B, the steps may further include driving or moving of either the test head 102 or the chuck 106, until the pressing structures 402 contact the solder bumps 202 and thereby press the solder bumps 202, prior to testing.

With reference to FIG. 5A, the substrate 112 may generally be planar or flat prior to pressing, as previously described. Each of the pressing structures 402 may include ends which may be integrally formed with, or conductively attached to, the substrate 112, in a manner completely or substantially similar to that of the probes 114, as previously described. Each of the pressing structures 402 may include a pressing base which may be completely or substantially similar to the probe base 304, as previously described. In various embodiments, the pressing base may be formed so as to be substantially flush with a surface of the substrate 112. The pressing base may include a pressing surface configured to perform pressing. In various embodiments of the present invention, a pitch of the pressing structures 402 across the substrate 112 may completely or substantially match that of the probes 114, as previously described, and may be, for example, approximately greater than 20,000 pressing structures per square inch. During pressing, each of the pressing structures 402 may be configured to make contact and thereby press a corresponding one of the solder bumps 202. In various embodiments, the card apparatus 404 may additionally include differences with respect to the substrate 112, which may be, for example, an organic substrate, a ceramic substrate, or a steel substrate.

Prior to testing, one or more pressing operations may be performed after the performance of the reflow process described above. Like above with respect to FIG. 2A and for illustrative purposes only, each of the solder bumps 202A-E are shown with exaggerated variations in height, relative to the reference line 204. For purposes of the present disclosure, the variations in height of the solder bumps 202A-E may form the first topology or surface topology, as previously described.

In embodiments of the present invention, a topology or surface topology formed by the pressing structures 402, and more particularly, by the pressing surfaces of the pressing structures 402, may exhibit variation which may resemble that of the probe tips 302 of the probes 114, as previously described. Such variation may be formed or caused in completely or substantially the same manner as that of the probes 114, as previously described.

With continued reference to FIG. 5A, the test head 102 or the chuck 106 may move, either individually or in combination, to align or position the pressing structures 402 with respect to the solder bumps 202, in a manner completely or substantially similar to that of the first test apparatus 100, as described above with reference to FIG. 2A. Alignment or positioning preferably occurs with respect to every chip of the wafer 108 that may be tested, as previously described, to ensure proper contact between the pressing structures 402 and corresponding solder bumps 202 during pressing, which may occur prior to testing.

With reference to FIG. 5B, the test head 102 or the chuck 106, either individually or in combination, may be driven or moved to affect the proper contact between the pressing structures 402 and the corresponding solder bumps 202, in a manner completely or substantially similar to that of the first test apparatus 100, as described above with reference to FIG. 2B. Driving preferably occurs with respect to every chip of the wafer 108 that may be tested, as previously described, to ensure proper contact between the pressing structures 402 and corresponding solder bumps 202 required for pressing. Travel by either of the test head 102 or the chuck 106 may occur in a manner completely or substantially similar to that of the first test apparatus 100, as described above with reference to FIG. 2B. For example, the chuck 106 may be driven a predetermined distance in the vertical direction, resulting in the desired contact between the pressing structures 402 and the corresponding solder bumps 202.

Preferably, the predetermined drive distance used during pressing will match the predetermined drive distance used during testing. Alternatively, or in combination, rather than driving the chuck 106 the predetermined distance, it may be driven until sufficient contact between the pressing structures 402 and the corresponding solder bumps 202 is established. Sufficient contact between the pressing structures 402 and the corresponding solder bumps 202 may be determined by, for example, measuring the electrical resistance at each of the pressing structures. The electrical resistance may be measured, for example, by way of the pressing circuitry of the card apparatus 404.

In various embodiments, the substrate 112 of the card apparatus 404 may experience deflection during pressing in a manner completely or substantially similar to that experienced by the substrate 112 of the card apparatus 104 during testing, as previously described above with reference to FIG. 2B. As such, the substrate 112 of the card apparatus 404 may experience a maximum deflection in a direction parallel with the Z-axis that may vary approximately from 5 to 15 micrometers, and more particularly from 8 to 10 micrometers. In an alternative embodiment, the substrate 112 may be made from metal such as steel, rather than the typical substrate materials disclosed above. A metal substrate may be configured to support larger pressing loads, for example, in the range of approximately 800 lbs.

Advantageously, the above pressing techniques may result in pressing of the solder bumps 202, such that the second topology of the solder bumps 202 may completely or substantially match, or conform to, a third topology of the pressing structures 402. Because the pressing structures 402 are substantially similar to the probes 114, but without probes tips, then the second topology of the solder bumps 202 will completely or substantially match, or conform to, the first topology of the probes 114. Stated differently, the variations in height of the solder bumps 202 produced by pressing, now after pressing, may completely or substantially match the variations in height of the pressing structures 402, as previously described, resulting in more uniform contact across the probes 114 and the solder bumps 202, and consequently enable low and uniform electrical resistance across the established interface during subsequent testing. Further, results produced by pressing may also reduce or eliminate the application of overdrive during testing, as previously described, reducing the degree to which flexing of the substrate 112 during testing may exacerbate inaccurate testing results, as previously described. This may be a result of, for example, similar flexing of the substrate 112 during pressing by the second testing apparatus 400.

For example, with continued reference to FIG. 5B, the one or more pressing operations performed with respect to each of the solder bumps 202 prior to testing may produce the second topology of the solder bumps 202 such that each of the probes 114, including those located about the perimeter and those located about the center of the substrate 112, may be in full contact with each of the solder bumps 202 during testing. The uniform contact with the solder bumps 202 may result in uniform and low contact resistance, thereby producing more accurate testing results. Further, the pressing techniques may result in reduced amounts of flexing of the substrate 112 during testing, as previously described, thereby supporting uniform contact and low contact resistance during testing. For purposes of the present disclosure, the two-dimensional curve of the substrate 112 is exaggerated in FIG. 5B, and is illustrated to be representative of flexing of the substrate 112 during pressing, in a manner completely or substantially similar to that during testing, as previously described with reference to FIG. 2B. Furthermore flexing of the substrate 112 is illustrated as a two-dimensional curve; in practice, it may manifest in three dimensions in a manner completely or substantially similar to that which may occur during testing, as previously described with reference to the first testing apparatus 100. As such, the flexing of the substrate 112 during pressing may account for the flexing of the substrate 112 during testing. As may be appreciated by those of skill in the art, the application of overdrive, or lack thereof, during pressing may be applied as appropriate.

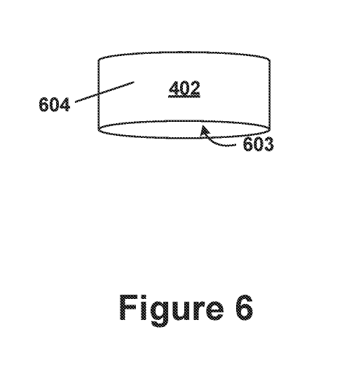

FIG. 6 depicts one of the pressing structures 402, in accordance with an embodiment of the present invention. Each pressing structure 402 may include a pressing surface 603, which may be formed as part of a pressing base 604. The pressing structures 402 represent testing structures configured for use with automated test equipment. As previously described, each of the pressing structures 402 may be used to electrically conduct signals between the test head 102 and the wafer 108 during pressing.

In an embodiment of the present invention, the pressing surface 603 and the pressing base 604 may be electrically conductive, and may be configured for electrical connection to the substrate 112, as previously described. The pressing surface 603 may be configured to contact and press a corresponding solder bump 202, as previously described, to thereby press the corresponding solder bump 202 of the with the wafer 108 prior to testing.

In an embodiment of the present invention, each of the pressing structures 402 may be formed of one or more electrically conductive materials, in a manner completely or substantially similar to that of the probes 114, as previously described. Additionally, each of the pressing structures 402, that is, with respect to the pressing base 604 and the pressing surface 603, either individually or in combination, may include metallic or alloy plating completely or substantially similar to that of the probes 114, as previously described. In various embodiments, portions of testing structures, such as the probes 114, may be used to form or produce the pressing structures 402. For example, the probe tips 302 of the probes 114, as previously described, may be removed to produce or form the pressing structures 402.

In an embodiment of the present invention, the pressing surface 603 may be shaped so as to include one or more facets or sides configured to perform pressing of solder bumps. The one or more facets may be configured to completely or substantially resemble the probe surface 303, as previously described. The pressing base 604 may be cylindrical or tubular in form, and may generally include a substantially circular cross-section. In various embodiments, the pressing base 604 may include a diameter of approximately 130 micrometers and a height of approximately 18 micrometers. The pressing surface 603 may be configured to exert a pressure upon a corresponding solder bump 202 during pressing, sufficient to shape or form the solder bump 202.

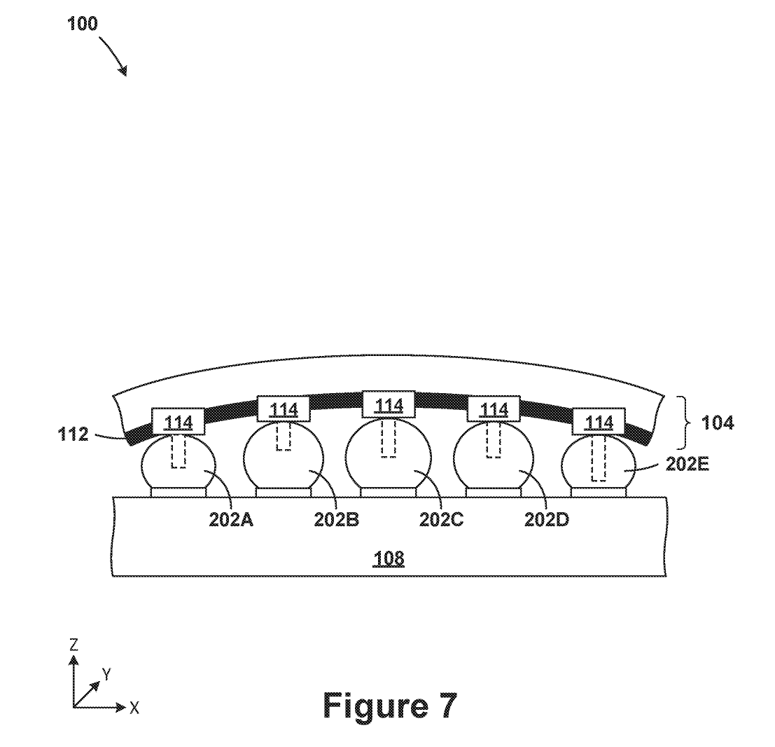

FIG. 7 depicts the section view, section A, with respect to the first test apparatus 100 of FIG. 1, during intermediate steps of a method of wafer testing, in accordance with an embodiment of the present invention. The steps may include aligning, not depicted, and driving, as depicted, until the probes 114 contact and interconnect with the solder bumps 202, as previously described. It should be noted that FIG. 7 illustrates testing after pressing has been performed by the second test apparatus 400, as previously described.

As depicted in FIG. 7, the second topology of the solder bumps 202 may, now after pressing, completely or substantially match the first topology of the probes 114. Further, it is apparent from FIG. 7, that each and every probe 114 comes into sufficient and uniform contact with each and every solder bump 202. Such uniform contact between the probes 114 and the solder bumps 202 results in more uniform contact resistance and thus more accurate test results.

What is claimed is:

1. A method of pressing a plurality of solder bumps prior to testing a wafer, the method comprising:
loading the wafer into a pressing apparatus, wherein the wafer comprises a plurality of chips;
aligning the wafer with respect to a test head of the pressing apparatus, wherein the test head comprises a substrate having a plurality of pressing structures disposed across a surface of the substrate facing the wafer, wherein a pressing structure pitch of the plurality of pressing structures matches a solder bump pitch of a plurality of solder bumps disposed across a surface of the wafer, and wherein the pressing structure pitch is greater than 20,000 pressing structures per square inch; and
causing the plurality of pressing structures to contact the plurality of solder bumps disposed across the surface of the wafer, wherein the plurality of solder bumps comprise a first surface topology and the plurality of pressing structures comprise a pressing surface topology prior to contact, wherein causing the contact comprises altering a shape of each of the plurality of solder bumps, such that the plurality of solder bumps comprise a second surface topology subsequent to the caused contact, and wherein the second surface topology of the plurality of solder bumps substantially matches the pressing surface topology subsequent to the caused contact.
